(19) United States
(12) Patent Application Publication
(10) Pub. No.: US 2023/0022795 A1
(43) Pub. Date: Jan. 26, 2023

(54) Dual-floating gates optoelectronic self-exciting synaptic memristor

(71) Applicant: BEIHANG UNIVERSITY, Beijing (CN)

(72) Inventors: Qin Gao, Beijing (CN); Anping Huang, Beijing (CN); Jiangshun Huang, Beijing (CN); Zhisong Xiao, Beijing (CN); Mei Wang, Beijing (CN)

(21) Appl. No.: 17/945,411

(22) Filed: Sep. 15, 2022

(30) Foreign Application Priority Data
Jul. 7, 2022 (CN) 202210793367.8

(51) Int. Cl. G06N 3/067; G06N 3/063

(52) U.S. Cl. CPC G06N 3/0675; G06N 3/063; H01L 29/788

(57) ABSTRACT

A dual-floating gates optoelectronic self-exciting synaptic memristor includes a bottom gate, a barrier layer coated on a surface of the bottom gate, a quantum dot layer coated on a surface of a middle portion of the barrier layer, two inverted L-shaped electron or hole tunneling layers coated on a surface of two end portions of the quantum dot layer respectively, two inverted L-shaped floating gate storage layers coated on the electron or hole tunneling layers respectively, two electron or hole blocking layers coated on the two floating gate storage layers respectively, an inverted L-shaped source electrode and an inverted L-shaped drain electrode coated on the two electron or hole blocking layers respectively, a photosensitive material layer coated on a surface of a middle portion of the quantum dot layer, and a top gate coated on the photosensitive material layer.

### CROSS REFERENCE OF RELATED APPLICATION

The present invention claims priority under 35 U.S.C. 119(a-d) to CN 202210793367.8, filed Jul. 7, 2022.

### BACKGROUND OF THE PRESENT INVENTION

### Field of Invention

The present invention relates to a dual-floating gates optoelectronic self-exciting synaptic memristor, which has the advantages of optoelectronic self-excitation, precise regulation of optoelectronic signals, low power consumption, simulating complex synaptic functions, regulating the stable operation of the neuromorphic computing system environment, and accelerating neuromorphic computing. It belongs to the field of brain-like computing device technology.

### Description of Related Arts

With the advent of the era of intelligence, AI (artificial intelligence) has become the core driving force which leads a new round of scientific and technical revolution and industrial transformation. Quantum computing, supercomputing and neuromorphic computing (which is also known as brain-like computing) are considered to be the three main paths to strong AI in the future. Among them, there has been widespread interest in neuromorphic computing inspired by the brain, and the key to realize neuromorphic computing lies in developing devices which are able to simulate the behavior of biological synapses, which is one of the important methods to overcome the “von Neumann bottleneck”. At present, the realization of neuromorphic computing is still a rather challenging task. How to obtain an artificial synaptic device with high bandwidth, low power consumption, adjustable weight, and high-density integration are the key problems that need to be solved first.

In recent years, devices used to simulate the behavior of biological synapses include field effect transistors (FETs), resistive random access memory (RRAM), and memristor (M). Among them, the conductance of the memristor is able to be continuously and reversibly regulated by electrical stimulation, which has transmission properties similar to biological synapses. The memristor is able to be used to simulate the pre-/post-synaptic membranes in biological synapse, and the migration of ions in the active layer simulate the conduction of neurotransmitters in the synaptic cleft. The emergence of memristor brings new opportunities for the development of artificial synapses. Memristor is considered to be one of the ideal choices for building neuromorphic computing architectures and realizing brain-like computing. Synaptic devices based on different physical mechanisms and functional materials have been developed and synaptic behaviors have been simulated. These synaptic behaviors depend on changes in synaptic weights under different stimuli, namely, synaptic plasticity, including homo-synaptic plasticity and heterosynaptic plasticity. Heterosynaptic plasticity is necessary and challenging to simulate the behaviors of biological synapse, such as associative learning and dynamic prevention of synaptic runaway. Considering factors such as bandwidth-connectivity-density, the neuromorphic computation of resistance state of the memristor induced by electrical stimulation alone still faces challenges, and optical or optoelectronic synergistic regulation provides a new approach. Optoelectronic neurosynaptic devices with high bandwidth, low crosstalk, low power consumption, and low latency are expected to promote the further development of high-performance neuromorphic computing and provide a potentially reliable strategy for developing novel neuromorphic computing systems and strong AI.

Although optoelectronic synaptic devices have made significant progress in their performance regulation and mechanism exploration, there are still many key scientific and technical difficulties that need to be overcome, especially in terms of device, architecture, and light controllability. At the device level, there is a lack of integrated consideration of materials, mechanisms, and optoelectronic device design. At present, there is a lack of simulation and description of the block coordination function in biological neural networks in terms of architecture, performance, and optoelectronic synergy in optoelectronic synaptic devices. In terms of architecture, although two-terminal devices are easier to be integrated into high-density arrays than three-terminal devices, two-terminal devices still face great challenges in realizing complex and high-order synaptic plasticity and maintaining a stable neuromorphic computing system environment. In terms of light controllability, light pulses are considered to be action potentials applied to the post-synaptic terminal, similar to external voltage stimulation of electrical synapses, and the conductance of the device is able to be changed by adjusting parameters such as wavelength and frequency of external light signals. However, although the direct irradiation method of external light source is simple, the light loss and controllability lead to obvious deficiencies in high bandwidth, parallel processing, and high-precision integration of devices.

### SUMMARY OF THE PRESENT INVENTION

Aiming at the current problems of optoelectronic synaptic memristors, the present invention combines the self-luminescence characteristics of quantum dots to construct a dual-floating gates optoelectronic self-exciting artificial synaptic device with optoelectronic synergistic effect, utilizes the chain action mechanism to realize the simulation and regulation of heterosynaptic plasticity, provides a new path for the exploration of the optoelectronic synergistic mechanism of optoelectronic memristors, and improves the optoelectronic performance of memristors. The device provided by the present invention is able to be applied to the simulation of artificial synapses, accelerate neuromorphic computing, and provide great application prospects for brain-like applications.

The key point of the present invention lies in combining the dual-floating gates, quantum dot luminescence, photosensitive memristor layer, and regulating the luminescence and annihilation of quantum dots through the dual-floating gates layer for inducing a change in the conductance of the photosensitive layer, so that the optoelectronic memristor achieves precise light generation and light annihilation control, which avoids the problem of optical loss caused by direct irradiation of external light sources and realizes the integration and controllability of optoelectronic signals. The present invention utilizes a conventional preparation method and has the feasibility of large-scale preparation. The present invention utilizes a novel device structure and a optoelectronic integrated architecture to solve the difficulties in the optical annihilation process of optoelectronic synaptic devices, and the precise regulation of optoelectronic signals.

The present invention adopts technical solutions as follows.

A dual-floating gates optoelectronic self-exciting synaptic memristor comprises a bottom gate, a barrier layer coated on a surface of the bottom gate, a quantum dot layer coated on a surface of a middle portion of the barrier layer, two inverted L-shaped electron or hole tunneling layers coated on a surface of two end portions of the quantum dot layer respectively, two inverted L-shaped floating gates storage layers coated on the electron or hole tunneling layers respectively, two electron or hole blocking layers coated on the two floating gate storage layers respectively, an inverted L-shaped source electrode and an inverted L-shaped drain electrode coated on the two electron or hole blocking layers respectively, a photosensitive material layer coated on a surface of a middle portion of the quantum dot layer, and a top gate coated on the photosensitive material layer.

Preferably, the bottom gate for providing holes is made from ITO (indium tin oxide) or fluorine-doped SnO₂ transparent conductive glass.

Preferably, the barrier layer is made from SiO₂, Ta₂O₅, HfO₂ or Al₂O₃ and has a thickness in a range of 1 to 2 nm.

Preferably, the quantum dot layer, which acts as a light source, is made from at least one member selected from the group consisting of CdTe, CdSe, InP, ZnS, CdS, PbS, CdS and perovskite. Through designing a proportion of a quantum dot solution, the best luminous effect is obtained. According to the actual material and integration situation, an appropriate proportion is selected to find a material with a wide wavelength luminous range as much as possible. Through limited experiments, the proportion is able to be obtained, so as to obtain a material ratio with a broad emission wavelength range.

The light-emitting process of the quantum dot layer is realized by applying an external electric field with different voltage intensities between one of the source electrode and the drain electrode and the bottom gate. Driven by the electric field, the one of the source electrode and the drain electrode and the bottom gate provide electrons and holes respectively to migrate to the quantum dot layer for forming excitons, so that the quantum dots emit light.

Preferably, the photosensitive material layer is made from perovskite or a two-dimensional material.

More preferably, the two-dimensional material is MoS₂, MoOₓ, MoSₓO₂₋ₓ, MoSe, MoS Se, BN, BP, graphene, or heterostructures thereof.

More preferably, the perovskite is one or two members selected from the group consisting of MAPbI₃, FAPbI₃, (PEA)PbI₃, CsPbI₃, CsPbBr₃, CsPbCl₃, MASnI₃, Cs₃Bi₂I₉, and Rb₃Bi₂I₉.

Preferably, the source and drain electrodes, dielectric layers and the floating gate storage layer form a source structure and a drain structure respectively; the two electron or hole tunneling layers and the two electron or hole blocking layers act as the dielectric layers.

Under an action of light generated by quantum, the vacancy defects inside the photosensitive material layer are able to migrate and converge in the photosensitive material layer, and finally a conductive filament-type passage is formed. Due to the optoelectronic effect, light creates carriers, resulting in enhanced on-state current of the device. By adjusting the magnitude (less than 4V) and direction of the writing voltage strength at the source and drain electrodes, the coupling and decoupling processes of electrons and holes in the quantum dot layer are regulated, so that the control of light generation and light quenching is realized, the precise control of light is realized, and the turn-on and reset of the device is realized.

Preferably, the top gate is made from Au or Pt.

Preferably, the source electrode and the drain electrode for providing electrons are made from Ag, Cu or Al.

Preferably, the dielectric layer comprises an electron or hole tunneling layer and an electron or hole blocking layer, and is made from SiO₂ or Al₂O₃.

Preferably, the floating gate storage layer at one side where the source electrode is provided is configured to store the electrons, the floating gate storage layer at another side where the drain electrode is provided is configured to store the holes.

Preferably, the dual-floating gates optoelectronic self-exciting synaptic memristor is manufactured by magnetron sputtering, atomic layer deposition, electron beam deposition, photoetching, wet etching or dry etching.

Also, the present invention provides a dual-floating gates optoelectronic self-exciting synaptic memristor array, which comprises N×M (N≥1 and M≥1) dual-floating gates optoelectronic self-exciting synaptic memristors, M source electrode connecting lines, M drain connecting electrode lines, M top gate connecting lines, and N bottom gate connecting lines, wherein M memristors on each row in the memristor array share a bottom gate connecting line, N memristors on each column in the memristor array share a top gate connecting line.

Also, the present invention provides a manufacturing method of a dual-floating gates optoelectronic self-exciting synaptic memristor. The dual-floating gates optoelectronic self-exciting synaptic memristor is manufactured on a substrate from bottom to top in a layer-by-layer manner by dry etching, wet etching, ultrasonic dispersion, transfer, magnetron sputtering, photoetching, atomic layer deposition and other methods. the manufacturing method comprises steps of:

(A) depositing a barrier layer on a bottom gate which is smooth and clean through atomic layer deposition technology;

(B) coating a quantum dot layer on a surface of the barrier layer through spin coating technology as a light source;

(C) depositing two electron or hole tunneling layers, two floating gate storage layers and two electron or hole blocking layers at a surface of two end portions of the quantum dot layer respectively by pulsed laser from bottom to top in sequence, wherein the two electron or hole tunneling layers and the two electron or hole blocking layers act as dielectric layers;

(D) preparing two inverted L-shaped Ag films as a source electrode and a drain electrode on the two electron or hole blocking layers by magnetron sputtering technology respectively;

(E) preparing a MoS₂ film as a photosensitive material layer on a surface of the quantum dot layer through transfer technology; and

(F) preparing a top gate, which is made from Au, on a surface of the photosensitive material layer through magnetron sputtering technology.

Preferably, the step (C) comprises:

(C1) depositing two first inverted L-shaped Al₂O₃ films as the two electron or hole tunneling layers at the surface of the two end portions of the quantum dot layer respectively through atomic layer deposition technology;

(C2) preparing the two inverted L-shaped floating gate storage layers on the two electron or hole tunneling layers respectively; and

(C3) depositing two second inverted L-shaped Al₂O₃ films as the two electron or hole blocking layers on the two inverted L-shaped floating gate storage layers respectively through atomic layer deposition technology, wherein the two electron or hole tunneling layers and the two electron or hole blocking layers encapsulate the two floating gate storage layers respectively.

Also, the present invention provides a method for realizing optoelectronic memristor effect with the dual-floating gates optoelectronic self-exciting synaptic memristor. The method comprises steps of:

(a) quantum dots emitting light, which comprises by connecting one of the source electrode and the drain electrode with ground and applying a continuous positive voltage pulses to the bottom gate, electrons and holes migrating from the one of the source electrode and the drain electrode and the bottom gate respectively, and forming excitons by coupling the holes with the electrons, so that the quantum dots emit light;

(b) writing, which comprises connecting the drain electrode with ground, controlling a luminous intensity of the quantum dot layer by adjusting a writing voltage strength at the source electrode under an action of an electric field, the photosensitive material layer receiving optical signals from the quantum dot layer and changing in resistance under light stimulation, and changing a resistance state of the memristor to a low resistance state; and

(C) erasing, which comprises by connecting the source electrode with ground and applying another continuous positive voltage pulses to the drain electrode, separating the electrons from the holes in the quantum dot layer, and changing the resistance state of the memristor to a high resistance state by gradually decreasing a conductance value of the photosensitive material layer.

By controlling input electrical pulses such as the pulse number, pulse width, pulse period and pulse amplitude, the luminous effect of the quantum dot layer of the memristor provided by the present invention is able to adjusted, so that the memristor has multiple storage states and is able to simulate the corresponding synaptic functions, such as learning-forgetting behaviors, and spike-timing-dependent plasticity (STDP).

The above-mentioned control process is able to be realized according to the existing experience of those skilled in the art. The number of pulses affects the relevant performance of the device. For example, the device will change from short-term memory to long-term memory with the number of pulses increases. The amplitude of pulses affects the luminous intensity of the quantum dots. The larger the amplitude, the stronger the electric field, the more electron-hole pairs provided, and the stronger the luminous intensity of the quantum dots.

Compared with the prior art, the dual-floating gates optoelectronic self-exciting synaptic memristor provided by the present invention combines the precise control of light by the dual-floating gates effect and the luminous characteristic of quantum dots, so that the memristor has the ability of optoelectronic self-excitation and controllable optoelectronic signal transmission, and the memristor array has the potential to be fabricated in a wide range. Moreover, the present invention has some advantages as follows.

(1) Compared with the existing optoelectronic self-exciting synaptic memristors, the present invention utilizes the regulation and response mechanism of the light generation or light quenching process in optoelectronic synaptic devices controlled by the dual-floating gates field effect, so as to achieve the adjustable synaptic plasticity simulation, and solve the optical loss and the poor optical controllability in optoelectronic synaptic devices.

(2) Under the action of the optoelectronic field, by studying the intrinsic relationship between photoconductivity changes and synaptic plasticity regulation in this structure, the memristor is able to be turned on and reset through optoelectronic synergistic excitation or inhibition acceleration.

(3) Through the combination of quantum dots and floating gates structure, the precise control of light pulses and the integration of optoelectronic synaptic device arrays are realized, which accelerates the application of optoelectronic synaptic devices in brain-like intelligence.

### BRIEF DESCRIPTION OF THE DRAWINGS

FIG. 1 is a structurally schematic diagram of a dual-floating gates optoelectronic self-exciting synaptic memristor provided by the present invention.

FIG. 2 is a structurally schematic diagram of a dual-floating gates optoelectronic self-exciting synaptic memristor array provided by the present invention.

FIG. 3a is a schematic diagram of the conduction mechanism of a dual-floating gates optoelectronic self-exciting device along a vertical direction.

FIG. 3b is a schematic diagram of the conduction mechanism of the dual-floating gates optoelectronic self-exciting device along a horizontal direction.

In the drawings, 101: top gate; 102: bottom gate; 103a: source electrode; 103b: drain electrode; 104: photosensitive material layer; 105: quantum dot layer; 106: floating gate storage layer; 107a: electron or hole tunneling layer; 107b: electron or hole blocking layer; 108: barrier layer; 201: source electrode connecting line; 202: top gate connecting line; 203: bottom gate connecting line; 204: dual-floating gates optoelectronic self-exciting synaptic memristor; 205: drain electrode connecting line; 301: hole; 302: electron.

### DETAILED DESCRIPTION OF THE PREFERRED EMBODIMENT

The present invention is further explained in detail with reference to embodiments and drawings as follows. The embodiments are intended to facilitate the understanding of the present invention, and the specific structural and functional details are only for the purpose of describing the exemplary embodiments and have no limitation on the present invention. Therefore, the present invention may be embodied in various forms, and the present invention should not be construed as limited only to the exemplary embodiments set forth again, but should cover all changes, equivalents and alternatives falling within the protective scope of the present invention.

First Embodiment:

FIG. 1 shows a dual-floating gates optoelectronic self-exciting synaptic memristor, which comprises a bottom gate 102, a barrier layer 108 coated on a surface of the bottom gate 102, a quantum dot layer 105 coated on a surface of a middle portion of the barrier layer 108, two inverted L-shaped electron or hole tunneling layers 107a coated on a surface of two end portions of the quantum dot layer 105 respectively, two inverted L-shaped floating gate storage layers 106 coated on the electron or hole tunneling layers 107a respectively, two electron or hole blocking layers 107b coated on the two floating gate storage layers 106 respectively, an inverted L-shaped source electrode 103a and an inverted L-shaped drain electrode 103b coated on the two electron or hole blocking layers 107b respectively, a photosensitive material layer 104 coated on a surface of a middle portion of the quantum dot layer 105, and a top gate 101 coated on the photosensitive material layer 104.

The bottom gate 102 is made from ITO (indium tin oxide) and has a thickness of 175 μm, the barrier layer 108 is made from SiO₂ and has a thickness in a range of 1 to 2 nm, the quantum dot layer 105 is made from PbS and has a thickness in a range of 5 to 10 nm, the photosensitive material layer 104 is made from MoS₂ and has a thickness in a range of 5 to 10 nm, the top gate 101 is made from Au and has a thickness of 50 nm, both of the source electrode 103a and the drain electrode 103b are made from Ag and have a thickness of 40 nm, both the electron or hole tunneling layers 107a and the electron or hole blocking layers 107b are made from Al₂O₃ and have a thickness in a range of 1 to 3 nm, and the floating gate storage layers 106 have a thickness in a range of 2 to 10 nm.

Second Embodiment:

The dual-floating gates optoelectronic self-exciting synaptic memristor according to the first preferred embodiment of the present invention is manufactured on a substrate from bottom to top in a layer-by-layer manner by dry etching, wet etching, ultrasonic dispersion, transfer, magnetron sputtering, photoetching, atomic layer deposition and other methods. The manufacturing process comprises steps of:

(A) depositing a barrier layer 108 on a bottom gate 102 which is smooth and clean through atomic layer deposition technology;

(B) coating a quantum dot layer 105 on a surface of the barrier layer 108 through spin coating technology as a light source;

(C) depositing two electron or hole tunneling layers 107a, two floating gate storage layers 106 and two electron or hole blocking layers 107b at a surface of two end portions of the quantum dot layer 105 respectively by pulsed laser from bottom to top in sequence, wherein the two electron or hole tunneling layers 107a and the two electron or hole blocking layers 107b act as dielectric layers, and the step (C) comprises:

(C1) depositing two first inverted L-shaped Al₂O₃ films as the two electron or hole tunneling layers 107a at the surface of the two end portions of the quantum dot layer 105 respectively through atomic layer deposition technology;

(C2) preparing the two inverted L-shaped floating gate storage layers 106 on the two electron or hole tunneling layers 107a respectively; and

(C3) depositing two second inverted L-shaped Al₂O₃ films as the two electron or hole blocking layers 107b on the two inverted L-shaped floating gate storage layers 106 respectively through atomic layer deposition technology, wherein the two electron or hole tunneling layers 107a and the two electron or hole blocking layers 107b encapsulate the two floating gate storage layers 106 respectively;

(D) preparing two inverted L-shaped Ag films as a source electrode 103a and a drain electrode 103b on the two electron or hole blocking layers 107b by magnetron sputtering technology respectively;

(E) preparing a MoS₂ film as a photosensitive material layer 104 on a surface of the quantum dot layer 105 through transfer technology; and

(F) preparing a top gate 101, which is made from Au and has a thickness of 50 nm, on a surface of the photosensitive material layer 104 through magnetron sputtering technology.

Third Embodiment:

A method for realizing optoelectronic memristor effect with the dual-floating gates optoelectronic self-exciting synaptic memristor according to the first preferred embodiment of the present invention is illustrated. The method comprises steps of:

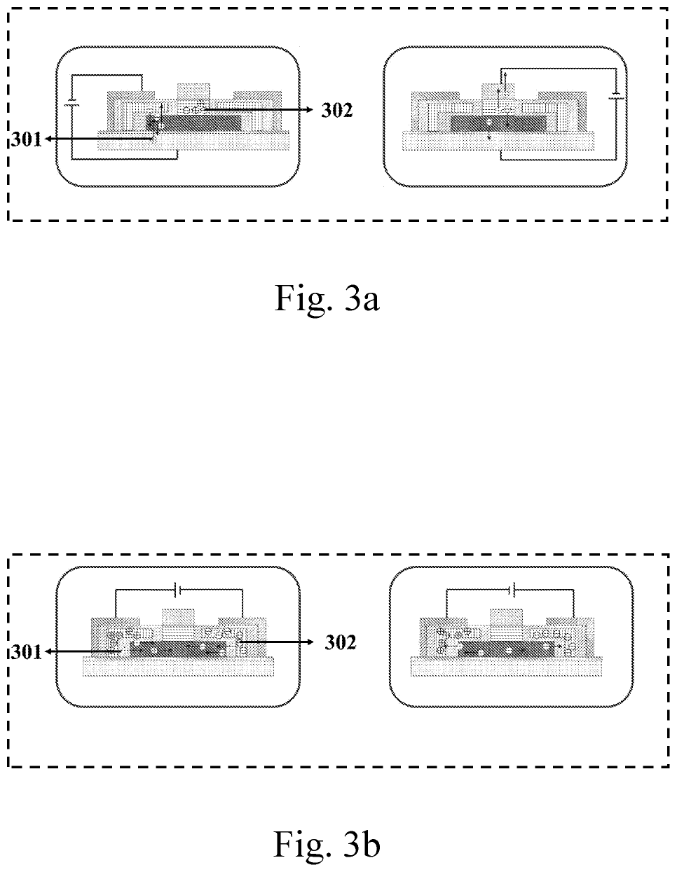

(a) as shown in FIG. 3a, during a writing process, a bottom gate 102 generating holes and one of a source electrode 103a and a drain electrode 103b generating electrons by applying a write signal between the one of the source electrode 103a and the drain electrode 103b and the bottom gate 102; driven by an electric field, the holes and the electrons entering a quantum dot layer 105 from two floating gate storage layers 106 for tunneling; forming excitons by coupling the holes with the electrons, quantum dots emitting light, controlling a luminous intensity of the quantum dots by writing pulse parameters at the source electrode 103a and the drain electrode 103b to achieve a change in a conductance of a photosensitive material layer 104, applying a forward bias voltage of 0 V to a top gate 101, and reading a current value of the memristor, thus realizing conductance regulation of the device, wherein:

the stronger the luminous intensity of the quantum dots, the greater the change in the conductance of the photosensitive material layer 104; the voltage at the source electrode 103a and the drain electrode 103b is in a range of 0 V to 4V; and (b) as shown in FIG. 3b, during an erasing process, decoupling the electrons and the holes by applying a reverse voltage between the source electrode 103a and the drain electrode 103b, separating the electrons from the holes under a drive of the reverse voltage, storing the electrons and the holes in two floating gate storage layers 106 respectively, the quantum dot quenching, and photocurrent gradually disappearing, thereby completing an activation.

This process well mimics the plasticity of neurobiological synapses.

By controlling the input electrical pulses parameter, such as number, pulse width, pulse period and pulse amplitude, the memristor provided by the present is able to adjust the value of high-resistance state and low-resistance state respectively, and simulate the corresponding synaptic functions, such as learning-forgetting behavior, spike-timing dependence plasticity (STDP) and other heterosynaptic plasticity.

The memristor provided by the present has high alignment and confinement in light control, and has obvious advantages in device energy consumption and neural function simulation.

Fourth Embodiment:

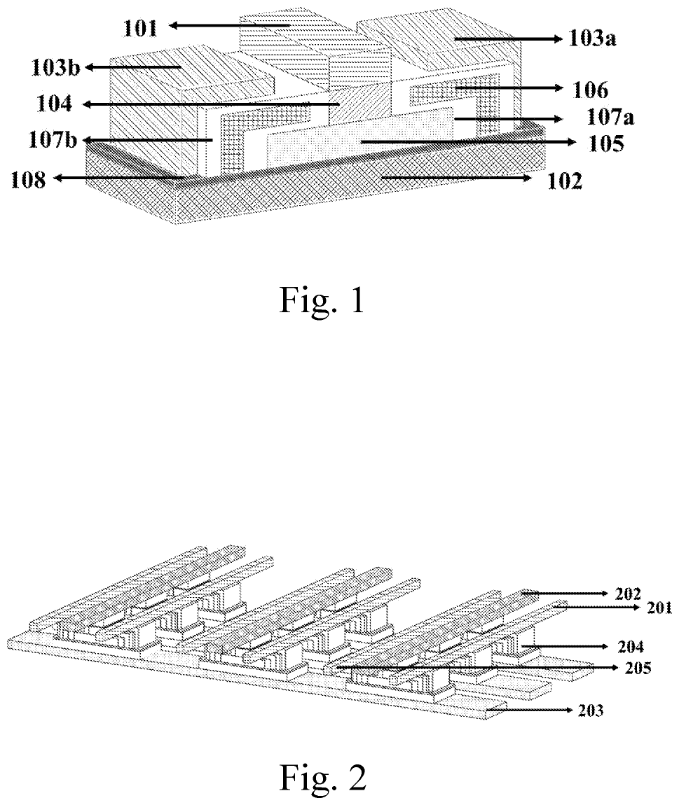

As shown in FIG. 4, a dual-floating gates optoelectronic self-exciting synaptic memristor array according to a fourth embodiment of the present invention is illustrated. The memristor array comprises N×M (N≥1 and M≥1) dual-floating gates optoelectronic self-exciting synaptic memristors 204, M source electrode connecting lines 201, M drain connecting electrode lines 205, M top gate connecting lines 202, and N bottom gate connecting lines 203. FIG. 2 shows a 4×4 dual-floating gates optoelectronic self-exciting synaptic memristor array. There are four dual-floating gates optoelectronic self-exciting synaptic memristors on each row in the memristor array, and the four memristors share a bottom gate connecting line 203. There are four memristors on each column in the memristor array, and the four memristors share a top gate connecting line 202. Accordingly, a cross array is formed.

The memristor array is able to simulate the corresponding synaptic function by combining multiple single-device functions, and realize applications such as logic operations, matrix operations, image recognition, and neuromorphic computing.

It should be noted that, in each embodiment of the present invention, in order to make those skilled in the art better understand the present invention, many technical details are put forward. However, even without these technical details and various changes and modifications based on the above embodiments, the technical solutions provided by in the present invention are able to be realized.

What is claimed is:

1. A dual-floating gates optoelectronic self-exciting synaptic memristor, comprising a bottom gate, a barrier layer coated on a surface of the bottom gate, a quantum dot layer coated on a surface of a middle portion of the barrier layer, two inverted L-shaped electron or hole tunneling layers coated on a surface of two end portions of the quantum dot layer respectively, two inverted L-shaped floating gate storage layers coated on the electron or hole tunneling layers respectively, two electron or hole blocking layers coated on the two floating gate storage layers respectively, an inverted L-shaped source electrode and an inverted L-shaped drain electrode coated on the two electron or hole blocking layers respectively, a photosensitive material layer coated on a surface of a middle portion of the quantum dot layer, and a top gate coated on the photosensitive material layer.

2. The dual-floating gates optoelectronic self-exciting synaptic memristor according to claim 1, wherein the bottom gate for providing holes is made from ITO (indium tin oxide) or fluorine-doped SnO₂ transparent conductive glass.

3. The dual-floating gates optoelectronic self-exciting synaptic memristor according to claim 1, wherein the quantum dot layer, which acts as a light source, is made from at least one member selected from the group consisting of CdTe, CdSe, InP, ZnS, CdS, PbS, CdS and perovskite.

4. The dual-floating gates optoelectronic self-exciting synaptic memristor according to claim 3, wherein a light-emitting process of the quantum dot layer is realized by applying an external electric field with different voltage intensities between one of the source electrode and the drain electrode and the bottom gate. Driven by the electric field, the one of the source electrode and the drain electrode and the bottom gate provide electrons and holes respectively to migrate to the quantum dot layer for forming excitons, so that the quantum dots emit light.

5. The dual-floating gates optoelectronic self-exciting synaptic memristor according to claim 1, wherein the photosensitive material layer is made from perovskite or a two-dimensional material;
the two-dimensional material is MoS₂, MoOₓ, MoSₓO₂₋ₓ, MoSe, MoSSe, BN, BP, graphene, or heterostructures thereof;
the perovskite is one or two members selected from the group consisting of MAPbI3, FAPbI₃, (PEA)PbI₃, CsPbI₃, CsPbBr₃, CsPbCl₃, MASnI₃, Cs₃Bi₂I₉, and Rb₃Bi₂I₉.

6. The dual-floating gates optoelectronic self-exciting synaptic memristor according to claim 1, wherein the source and drain electrodes, dielectric layers and the floating gate storage layer form a source structure and a drain structure respectively; the two electron or hole tunneling layers and the two electron or hole blocking layers act as the dielectric layers.

7. The dual-floating gates optoelectronic self-exciting synaptic memristor according to claim 6, wherein the source electrode and the drain electrode for providing electrons are made from Ag, Cu or Al.

8. The dual-floating gates optoelectronic self-exciting synaptic memristor according to claim 6, wherein each of the dielectric layers comprises an electron or hole tunneling layer and an electron or hole blocking layer, and is made from SiO₂ or Al₂O₃.

9. The dual-floating gates optoelectronic self-exciting synaptic memristor according to claim 6, wherein the floating gate storage layer at one side where the source electrode is provided is configured to store the electrons, the floating gate storage layer at another side where the drain electrode is provided is configured to store the holes.

10. A manufacturing method of the dual-floating gates optoelectronic self-exciting synaptic memristor according to claim 1, wherein:
the dual-floating gates optoelectronic self-exciting synaptic memristor is manufactured on a substrate from bottom to top in a layer-by-layer manner by dry etching, wet etching, ultrasonic dispersion, transfer, magnetron sputtering, photoetching, or atomic layer deposition;
the manufacturing method comprises steps of:
(A) depositing the barrier layer on the bottom gate which is smooth and clean through atomic layer deposition technology;
(B) coating the quantum dot layer on a surface of the barrier layer through spin coating technology as a light source;
(C) depositing two electron or hole tunneling layers, two floating gate storage layers and two electron or hole blocking layers at a surface of two end portions of the quantum dot layer respectively by pulsed laser from bottom to top in sequence, wherein the two electron or hole tunneling layers and the two electron or hole blocking layers act as dielectric layers, the step (C) comprises:
(C1) depositing two first inverted L-shaped Al₂O₃ films as the two electron or hole tunneling layers at the surface of the two end portions of the quantum dot layer respectively through atomic layer deposition technology;
(C2) preparing the two inverted L-shaped floating gate storage layers on the two electron or hole tunneling layers respectively; and
(C3) depositing two second inverted L-shaped Al₂O₃ films as the two electron or hole blocking layers on the two inverted L-shaped floating gate storage layers respectively through atomic layer deposition technology, wherein the two electron or hole tunneling layers and the two electron or hole blocking layers encapsulate the two floating gate storage layers respectively;
(D) preparing two inverted L-shaped Ag films as the source electrode and the drain electrode on the two electron or hole blocking layers by magnetron sputtering technology respectively;
(E) preparing a MoS₂ film as the photosensitive material layer on a surface of the quantum dot layer through transfer technology; and
(F) preparing the top gate, which is made from Au, on a surface of the photosensitive material layer through magnetron sputtering technology.

11. A dual-floating gates optoelectronic self-exciting synaptic memristor array, which comprises N×M (N≥1 and M≥1) dual-floating gates optoelectronic self-exciting synaptic memristors according to claim 1, M source electrode connecting lines, M drain connecting electrode lines, M top gate connecting lines, and N bottom gate connecting lines, wherein M memristors on each row in the memristor array share a bottom gate connecting line, N memristors on each column in the memristor array share a top gate connecting line.
